(19) United States
(12) Patent Application Publication
(10) Pub. No.: US 2017/0207405 A1
(43) Pub. Date: Jul. 20, 2017

(54) MULTI-TERMINAL TANDEM CELLS

(71) Applicants: COMM. A L'ENERGIE ATOMIQUE ET AUX ENERGIES ALT., Paris (FR); UNIV DE CHAMBERY - UNIVERSITE SAVOIE MONT BLANC, Chambéry (FR)

(72) Inventors: Tristan LESCOUET, Grenoble (FR); Solenn BERSON, Chambéry (FR); Caroline CELLE, Firminy (FR); Pierre-Balthazar LECHENE, Paris (FR); Jean-Pierre SIMONATO, Sassenage (FR)

(73) Assignees: COMM. A L'ENERGIE ATOMIQUE ET AUX ENERGIES ALT., Paris (FR); UNIV DE CHAMBERY - UNIVERSITE SAVOIE MONT BLANC, Chambéry (FR)

(21) Appl. No.: 15/321,341

(22) PCT Filed: Jun. 23, 2015
(86) PCT No.: PCT/EP2015/064141

§ 371 Date: Dec. 22, 2016

(30) Foreign Application Priority Data
Jun. 26, 2014 (FR) 1455994

(51) Int. Cl. H01L 51/44; H01L 51/42; H01L 51/00; H01L 27/30

(52) U.S. Cl. CPC H01L 51/445; H01L 27/302; H01L 51/4293; H01L 51/0003; H01L 2251/301; H01L 2251/303; H01L 51/0037; H01L 51/0036; H01L 51/004; H01L 51/0039; H01L 51/0047

(57) ABSTRACT

The present disclosure relates to a multi-layer stack which is useful for forming a multi-junction organic photovoltaic cell, said stack including first and second active layers, and an intermediate p-type or n-type layer, inserted between said first and second active layers and in contact with at least one of the first and second active layers, said intermediate layer including a network of electrically conductive nanowires, said stack including an additional layer, inserted between the first active layer and the second active layer and directly in contact with the first active layer or the second active layer, the additional layer being P-type or N-type, separate from the one forming the intermediate layer.

The present invention relates to the field of organic photovoltaic cells.

Organic photovoltaic cells generally comprise a multilayer stack comprising a photoactive layer, known as an “active” layer. This active layer is referred to as “I” and in general it consists of one or more intrinsic semiconductor materials or of a mixture of p-type and n-type materials. These semiconductor materials are generally organic molecules or polymers or halogenated organometallic compounds. This active layer is in contact on either side with an n-type layer and a p-type layer. The p-type layer generally consists of a mixture of poly(3,4-ethylenedioxythiophene) (PEDOT) and of sodium poly(styrene sulfonate) (PSS), or of a p-type semiconductive oxide, for example WO₃, MoO₃, V₂O₅ or else NiO. The n-type layer generally consists of an n-type semiconductive oxide, for example ZnO, AZO (aluminum-doped zinc oxide) or TiOₓ. This type of multilayer assembly, formed from the superposition of the active layer I and of the two p-type and n-type layers described above, is conventionally referred to as NIP or PIN.

The electrical efficiency of an organic photovoltaic cell is particularly dependent on the light absorption spectrum of the active layer.

In order to improve this efficiency, organic photovoltaic cells of multi junction type, and in particular of “tandem” or double junction type, are produced. Such tandem-type cells comprise two PIN and/or NIP multilayer assemblies as described above, stacked on one another, and the respective active layers of which generally have different light absorption spectra. It should be noted that in the case of tandem-type organic photovoltaic cells, the NIP or PIN multilayer assembly is generally designed as a single junction. In these tandem-type cells, the photons not absorbed by the first active layer may be absorbed by the second active layer. The amount of photons recovered by all of the active layers of the cell is thus increased and the electric efficiency of the latter is improved.

By way of illustration of tandem-type organic photovoltaic cells, mention may very particularly be made of “2-terminal” cells and “3-terminal” cells.

In a 2-terminal cell, the multilayer stack defines a series electrical connection. The upper layer of the lower multilayer assembly, of n- or p-type, forms with the lower layer of the upper multilayer assembly, respectively of p- or n-type, a multilayer element for recombination of the charge carriers (electrons and holes), the thickness of which is generally between 40 nm and 200 nm. In order to recombine the charge carriers more efficiently, a metal and semi-transparent layer, in particular made of silver, may be inserted which substantially completely covers the interface between the two layers forming said multilayer recombination element.

Nevertheless, the intensity J of the current in a 2-terminal cell remains limited by the least efficient multilayer assembly.

“3-terminal” cells make it possible in particular to overcome this handicap.

Thus, the “3-terminal” cell described in the article “High-efficiency polymer tandem solar cells with three terminal structure”, Srivinas Sista et al., Adv. Mater., 2010, 22, E77-E80, consists of an assemblage formed from an NIP multilayer assembly superposed on a PIN multilayer assembly, first and second electrodes placed on either side and in contact with each NIP or PIN multilayer assembly, and a central electrode, formed from a layer of gold, placed at the interface between the two NIP and PIN multilayer assemblies. In such an assemblage, the lower and upper electrodes are in contact and are connected to the central electrode, so as to form a parallel connection of the PIN and NIP multilayer assemblies. Thus, the total current J in this type of photovoltaic cell does not turn out to be affected by a potential current difference between the two respectively PIN and NIP multilayer assemblies.

As described above, an assemblage of aforementioned tandem type additionally incorporates a metal layer. However, the use of this metal layer imposes certain constraints.

Thus, the metal layer located at the interface between the PIN and/or NIP multilayer assemblies of the assemblage should not be too thick for the purposes of guaranteeing a high transmission so that the photons may, after having passed through the first active layer and the metal layer, reach the second active layer. However, it is known, as attested to by the article “Highly efficient organic tandem solar cells: a follow up review”, Ameri Tabeyeh et al., that a reduction in the thickness of this metal layer may give rise to conduction problems, detrimental to the efficiency of the photovoltaic cell.

Finally, in contrast with the active layers, of n-type and p-type, conventionally deposited via a wet route, the deposition of this metal layer requires a vacuum evaporation technique. Industrially, this technique proves expensive and not easy to implement.

Alternatives to the metal electrodes are already known. They benefit from other conductive materials such as mixtures of polymers, for example of PEDOT and PSS, metal-polymer composites, metal grids, metal nanowires, carbon nanotubes, graphene, and metal oxides. In the article “Flexible ITO-Free Polymer Solar Cells”, Dechan Angmo, Frecerik C. Krebs, J. Appl. Polym. Sci., vol. 129, num. 1, 1-14, 2013, DOI: 10.1002/app.38854., the use, as transparent upper electrode, of an array of silver nanowires is in particular proposed. However, the high roughness of the array of nanowires may lead to the creation of short circuits. In addition, the empty zones between the silver nanowires limit the charge extraction capacity between the adjacent n or p layer and the electrode. Finally, the work function of the array of silver nanowires is not suitable for charge extraction.

Consequently, there remains a need for a multilayer stack for an organic cell of multi junction type, in particular of tandem type with 2 or more terminals, the development of which is free, at least in part, of the problems described above.

The object of the present invention is specifically to meet this expectation.

Thus, according to a first of its aspects, the present invention relates to a multilayer stack useful for forming an organic photovoltaic cell of multi-junction type, in particular of tandem type, said stack comprising first and second active layers, and a p-type or n-type intermediate layer, inserted between said first and second active layers and in contact with at least one of the first and second layers, characterized in that said intermediate layer incorporates an array of electrically conductive nanowires.

Against all expectation, the inventors have indeed observed that a stack according to the invention proves particularly advantageous for forming a photovoltaic cell of multi junction type, in particular of tandem type.

Firstly, it makes it possible to attain an advantageous compromise in terms of surface resistivity and transmittance.

Furthermore, the array of nanowires may have a thickness greater than that of a metal layer, but less than that of the layer that it incorporates. The conductive array thus formed allows an efficient recombination or extraction of the charge transporters with a small reduction in the transmittance of the stack relative to a stack that does not comprise the array of nanowires.

Thus, an organic photovoltaic cell of multi junction type, and in particular of tandem type, comprising a stack according to the invention, has an improved energy efficiency relative to the organic photovoltaic cells of multi-junction type, and in particular of tandem type, of the prior art.

The invention also relates to a process for manufacturing a multilayer stack according to the invention, comprising at least the steps consisting in:

a) placing a first active layer in contact with a first coating of p-type or n-type,

b) depositing on said first coating a first solution comprising nanowires and optionally a p-type or n-type material, under conditions suitable for the formation, at the surface of said first coating, of a second coating incorporating an array of nanowires,

c) optionally, depositing on the second coating formed in step b) a second solution comprising a p-type or n-type material, identical to or different from that of the first solution, under conditions suitable for the formation of a third coating.

The process according to the invention is simpler to implement and less expensive than processes for manufacturing stacks comprising a step of vacuum evaporation of a metal layer of the prior art. In particular, all of the coating deposition steps for forming the multilayer stack according to the invention may be carried out via a wet route. In addition, all the steps of depositing the various layers of the stack may thus be carried out with the same deposition device.

The invention also relates to a photovoltaic cell of multi-junction type and in particular of tandem type, comprising a multilayer stack according to the invention or obtained by means of a process according to the invention.

Advantageously, the multilayer recombination element may be thicker than in a 2-terminal tandem-type organic photovoltaic cell of the prior art, while having a substantially identical transmittance. It is thus possible to adjust the optical field of the multilayer recombination element in order to increase the amount of photons collected by the active layers, and without loss of surface resistivity or mobility of the charge carriers.

The invention will be better understood on reading the following detailed description and on examining the appended drawing, in which:

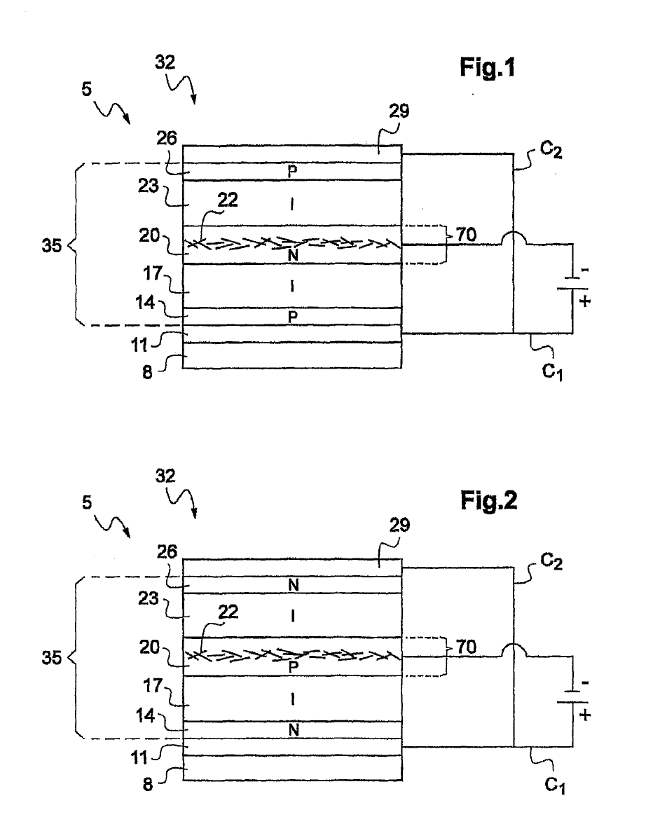

FIGS. 1 and 2 illustrate stacks of 3-terminal tandem-type organic photovoltaic cells according to the invention,

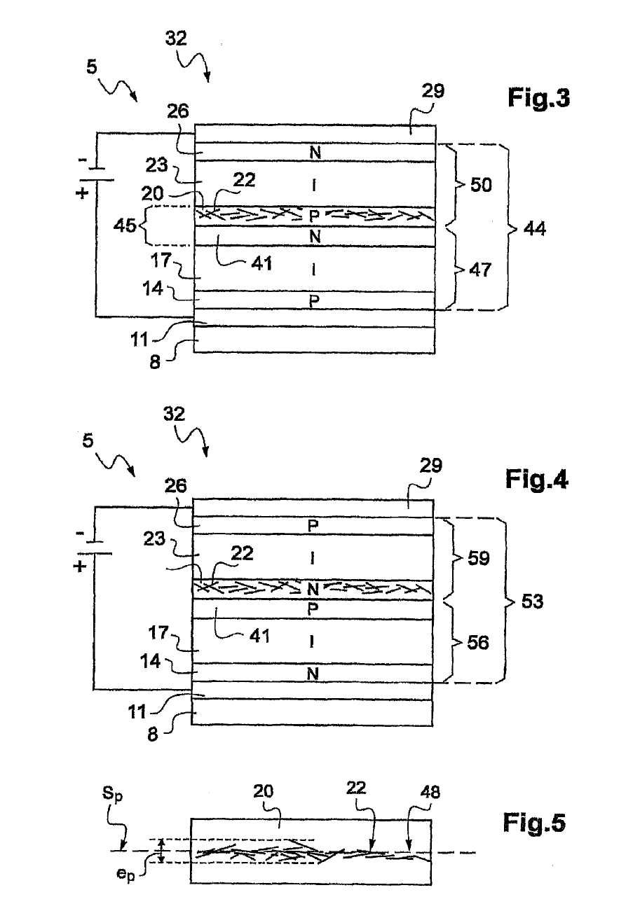

FIGS. 3 and 4 illustrate stacks of 2-terminal tandem-type organic photovoltaic cells according to the invention,

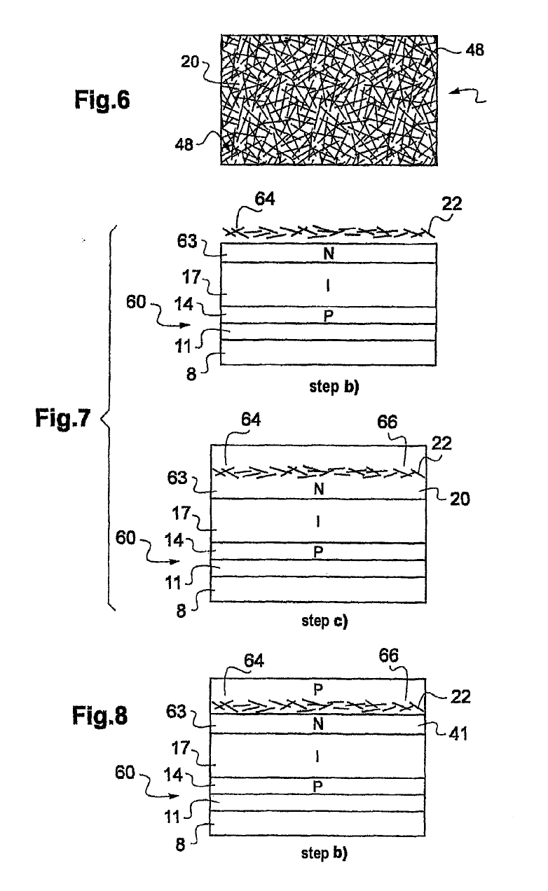

FIGS. 5 and 6 illustrate an intermediate layer that incorporates an array of nanowires of a stack according to the invention, as side view and as top view respectively, and

FIGS. 7 and 8 illustrate steps of the process for manufacturing a stack according to various embodiments.

In the various figures, identical or similar members are labelled with the same reference. In the appended drawing, the actual proportions of the various constituent elements of the stack have not always been respected for the sake of clarity.

Stack

As is illustrated for example in FIG. 1, a stack 5 according to the invention may in particular comprise a succession of superposed layers that are contiguous with one another in the following order:
a first outer layer 14,
a first active layer 17,
an intermediate layer 20 that incorporates an array 22 of nanowires,
a second active layer 23, and
a second outer layer 26.

As will be seen subsequently, in one particular embodiment, the stack may also comprise an additional layer placed between the first active layer or the second active layer on the one hand and the intermediate layer on the other hand.

In a first embodiment of the invention, the multilayer stack is more particularly intended to be used to form a 3-terminal tandem-type organic photovoltaic cell. In this case, the intermediate layer is directly in contact with the first and second active layers. In other words, the stack does not then comprise an additional layer.

More particularly, as illustrated in FIG. 1, the stack according to the first embodiment forms a PINIP-type multilayer assemblage 35, consisting of a p-type first outer layer, a first active layer, an n-type intermediate layer, a second active layer and a p-type second outer layer.

As a variant, as illustrated in FIG. 2, the stack forms an NIPIN-type multilayer assemblage 38, consisting of the n-type first outer layer, the first active layer, the p-type intermediate layer, the second active layer and the n-type second outer layer.

As is illustrated in FIGS. 1 and 2, the array 22 of nanowires of the stack according to the first embodiment of the invention is preferably placed substantially halfway from the interface between the first active layer and the intermediate layer on the one hand, and from the interface between the second active layer and the intermediate layer on the other hand. It is intended to form the central electrode of the 3-terminal tandem-type organic photovoltaic cell. Preferably, in this variant, the nanowires that form the array are metallic, and in particular comprise, or even consist of, a metal selected from silver, gold, copper and alloys thereof. Silver is a preferred metal.

In a second embodiment of the invention illustrated in FIGS. 3 and 4, the multilayer stack is more particularly intended to be used to form a 2-terminal tandem-type organic photovoltaic cell. In this case, the stack comprises an additional layer 41, inserted between the first active layer and the second active layer and directly in contact with the first active layer or with the second active layer, the additional layer being of p- or n-type, different from that forming the intermediate layer 20.

Preferably, the additional layer is inserted between the intermediate layer on the one hand and the first active layer or the second active layer on the other hand, and is in contact with the intermediate layer on the one hand and with the first active layer or with the second active layer on the other hand.

More particularly, a stack according to the second embodiment may form a PINPIN-type multilayer assemblage 44 consisting of a first PIN-type multilayer assembly 47 comprising a p-type first outer layer, a first active layer, an n-type intermediate layer or an n-type additional layer, and of a second PIN-type assembly 50 comprising a p-type additional layer or a p-type intermediate layer, a second active layer and an n-type second outer layer. One such example of a PINPIN-type stack is illustrated in FIG. 3.

As a variant, as illustrated in FIG. 4, a stack according to the second embodiment may form an NIPNIP-type multilayer assemblage 53 consisting of a first NIP-type multilayer assembly 56 comprising an n-type first outer layer, a first active layer, a p-type intermediate layer or a p-type additional layer, and of a second NIP-type multilayer assembly 59 comprising an n-type additional layer or an n-type intermediate layer, a second active layer and a p-type second outer layer.

According to the second embodiment of the invention, as is illustrated in FIGS. 3 and 4, the array 22 of nanowires is preferably at least partially in contact with the additional layer, and preferably extends to the interface between the intermediate layer and the additional layer. Thus, the assembly formed by the intermediate layer incorporating the array of nanowires and the additional layer forms a multilayer charge recombination element for the 2-terminal tandem-type organic photovoltaic cell.

Array of Nanowires

The array of nanowires of the stack is formed from an irregular and disordered assemblage of nanowires. In particular, the array of nanowires has no characteristic distance according to which an elementary and characteristic pattern of the array is reproduced. Thus, an array is different from a grid.

Preferably, the array 22 of nanowires extends parallel to the intermediate layer 20. Preferably, less than 5%, less than 1%, or even substantially none of the nanowires of the array of nanowires is in contact with the first active layer and/or the second active layer. Preferably, the array of nanowires has no contact with said first and second active layers.

As is schematically illustrated in FIG. 5, the array 22 of nanowires preferably extends along a substantially planar surface Sₚ, referred to as array plane below, preferably parallel to the interface between the intermediate layer 20 and the layer immediately above and/or immediately below and in contact with the intermediate layer.

Preferably, the nanowires forming the array of nanowires may be distributed isotropically within this array as may be seen in FIG. 6.

Preferably, the distribution of the nanowires within the array of nanowires is homogeneous.

Preferably, the density of nanowires of the array, expressed as equivalent mass of silver per unit area, is between 0.01 g/m² and 0.05 g/m². The amount of nanowires expressed as equivalent mass of silver forming the nanowires is considered to mean the total mass of the volume of the nanowires considered that would be formed of silver, irrespective of the material that forms the nanowires.

Preferably, the thickness eₚ of the array of nanowires is less than 300 nm, preferably less than or equal to 200 nm, and is more particularly between 40 nm and 200 nm.

Preferably, the intermediate layer, observed along a vertical direction, is such that the surface fraction occupied by the array of nanowires represents less than 80%, less than 50%, less than 30%, or even less than 10%.

In the case of a 3-terminal tandem-type organic photovoltaic cell, the nanowires of the array 22 of nanowires have points of contact with different nanowires of the array of nanowires. Reference is then made to percolation between the nanowires, which enables the array 22 to act as central electrode for the photovoltaic cell. The array of nanowires may also be percolating when the stack that comprises it is intended for a 2-terminal tandem-type photovoltaic cell.

In particular, in the case of a 2-terminal tandem-type organic photovoltaic cell, the array 22 of nanowires does not necessarily need to be percolating since the assembly formed with the intermediate layer and the additional layer is intended to form a multilayer element for recombination of charge carriers.

Thus, in one embodiment variant, in particular, the array of nanowires is not percolating, that is to say that the nanowires have no contact with one another.

The ability of the array of nanowires to extract the charges from the adjacent layer may be evaluated by measuring its work function. In the case where the array of nanowires consists of silver nanowires and/or of copper nanowires, the work function of the array of nanowires is preferably between 4.7 eV and 5.2 eV.

Preferably, the nanowires that constitute the array are metallic, and in particular comprise, or even consist of, a metal selected from silver, gold, copper and alloys thereof. Silver is a preferred metal.

Preferably, the nanowires have a mean diameter greater than 10 nm, preferably greater than 20 nm, and less than 1000 nm, preferably less than 150 nm. Preferably, they have a mean length greater than or equal to 1 μm and less than or equal to 500 μm, preferably less than or equal to 30 μm. In particular, the mean slenderness ratio of the nanowires is preferably greater than 100.

The diameter of a nanowire may be between 10 nm and 1000 nm. The length of a nanowire may be between 1 μm and 100 μm, preferably between 5 μm and 20 μm.

Preferably, more than 70%, more than 90%, or even substantially all of the nanowires have an aspect ratio of greater than 100.

Intermediate Layer

The array of nanowires is incorporated into an intermediate layer that advantageously has at least one of the features described above.

It is formed at least partly, or even completely, from a p-type or n-type material. An n-type material allows the transport of electrons. A p-type material allows the transport of holes. A p-type or n-type material may be a conductive or semiconductive oxide, or a conductive or semiconductive polymer.

The p-type material may for example be selected from poly(3,4-ethylenedioxythiophene) (PEDOT): sodium poly(styrene sulfonate) (PSS), Nafion, WO₃, MoO₃, V₂O₅ and NiO, and mixtures thereof.

A preferred p-type material is the mixture of PEDOT and PSS.

An n-type material may for example be selected from polyethylenimine ethoxylated (PEIE), poly[(9,9-bis(3′-(N,N-dimethylamino)propyl)-2,7-fluorene)-alt-2,7-(9,9-dioctylfluorene) (PFN), ZnO, titanium oxides TiOₓ with x between 1 and 2, aluminum-doped zinc oxide (AZO), indium-doped zinc oxide (IZO), gallium-doped zinc oxide (GZO), and mixtures thereof.

Preferred n-type materials are ZnO and TiOₓ.

In the case where the intermediate layer comprises an n-type material, the work function of the array of nanowires is preferably between 4.0 eV [electronvolt] and 4.8 eV. In the case where the intermediate layer comprises a p-type material, the work function of the array of nanowires is preferably between 4.8 eV and 5.3 eV.

According to the first embodiment of the invention, preferably, the thickness of the intermediate layer is greater than or equal to 100 nm and less than or equal to 500 nm. It may be measured with an atomic force microscope AFM of VEECO/INNOVA trade name or with a profilometer of KLA Tencor trade name.

Preferably, according to the first embodiment, the transmittance of the intermediate layer is greater than 50% and/or the surface resistivity of the intermediate layer is less than 200 Ω/sq, preferably less than 100 Ω/sq.

According to the second embodiment of the invention, preferably, the thickness of the intermediate layer is greater than or equal to 100 nm and less than or equal to 500 nm.

Other Layers of the Stack

As described above, according to the second embodiment, the stack comprises an additional layer made of a p-type or n-type material different from that of the intermediate layer, in particular made of a p- or n-type polymer and/or made of a p- or n-type oxide respectively, as described above.

Preferably, the intermediate layer is then made of ZnO and the additional layer is then made of a mixture of PEDOT and PSS.

As a variant, the intermediate layer is made of a mixture of PEDOT and PSS and the additional layer is made of ZnO.

The additional layer preferably has a thickness of between 50 nm and 300 nm.

The assembly formed by the intermediate layer and the additional layer preferably has a thickness greater than or equal to 100 nm and less than or equal to 500 nm. Preferably, the transmittance of the assembly formed by the intermediate layer and the additional layer is greater than 50% and/or the surface resistivity of the assembly formed by the intermediate layer and the additional layer is less than 200 Ω/sq, preferably less than 100 Ω/sq.

According to the embodiment, the stack also comprises first and second active layers positioned on either side of the intermediate layer, and where appropriate of the additional layer.

The first active layer may be made of a mixture of materials different from that of the second active layer, so as to have a light absorption spectrum different from the spectrum of the second active layer.

It may also be formed from the same mixture of materials.

The choice of the materials and the thicknesses of the first and second active layers may be made conventionally in the field of multi junction organic photovoltaic cells. The materials chosen are in particular organic molecules and/or polymers. According to one variant, the material(s) of the active layers could be selected from halogenated organometallic compounds such as CH₃NH₃PbI₂, the lead possibly being replaced by tin or germanium and the iodine possibly being replaced by chlorine or bromine. Such a photovoltaic cell may in this case be referred to as a perovskite photovoltaic cell, on account of the material constituting the active layer(s), the architecture of such a cell nevertheless being identical to that of a multi junction organic photovoltaic cell. Thus, within the context of the present invention, such a perovskite photovoltaic cell may be likened to a multi-junction organic photovoltaic cell.

By way of illustration, a stack according to the first embodiment of the invention may comprise:
a first active layer consisting of a mixture of P3HT and PCBM,
an intermediate layer that incorporates an array of silver nanowires and consists of ZnO, and
a second active layer consisting of a mixture of P3HT and PCBM.

As preferred variant, a stack according to the first embodiment of the invention may comprise:
a first active layer consisting of a mixture of P3HT and PCBM,
an intermediate layer that incorporates an array of silver nanowires and consists of a mixture of PEDOT and PSS, and
a second active layer consisting of a mixture of P3HT and PCBM.

For its part, a stack according to the second embodiment of the invention may comprise:
a first active layer consisting of a mixture of P3HT and PCBM,
an additional layer consisting of a mixture of PEDOT and PSS,
an intermediate layer that incorporates an array of silver nanowires and consists of ZnO,
a second active layer consisting of a mixture of P3HT and PCBM.

As preferred variant, a stack according to the second embodiment of the invention, comprising a p-type intermediate layer and an n-type additional layer, may comprise:
a first active layer consisting of a mixture of P3HT and PCBM,
an additional layer consisting of ZnO,
an intermediate layer that incorporates an array of silver nanowires and consists of a mixture of PEDOT and PSS,
a second active layer consisting of a mixture of P3HT and PCBM.

In particular, as illustrated in FIGS. 1 to 4, the stack may also comprise first and second outer layers.

Preferably, the first and second outer layers are made of an n- or p-type material, preferably selected from n- or p-type polymers and/or oxides as described above for forming the intermediate layer. The constituent materials of the first and second outer layers may be different. As a variant, they are identical.

The thickness of the first outer layer and/or the second outer layer may be greater than 20 nm, or even greater than 50 nm and/or less than 250 nm, or even less than 200 nm, or else less than 100 nm.

Manufacturing Process

The process for manufacturing a stack according to the invention is such that all of the deposition steps for forming the stack according to the invention may be carried out via a wet route, that is to say via a technique that carries out the deposition of a liquid solution.

In particular, the deposition of a solution during the manufacturing process may be carried out by means of a technique selected from spin coating, knife coating, ultrasonic spray coating, slot-die coating, inkjet printing, photogravure, flexography or screen printing. In particular, all the coatings deposited during the steps of the process may be deposited using a single technique selected from those described above. In particular, the deposition technique may also be selected by a person skilled in the art on the basis of the fluid properties and constituents of the solution to be deposited. A layer may be obtained by at least one, or even several, deposition steps.

Preferably, a solution deposited during the implementation of the process comprises a solvent. The solvent may be water and/or dimethyl sulfoxide and/or an alcohol, for example selected from isopropanol, ethanol, methanol, glycerol, ethylene glycerol, or mixtures thereof.

The features specific to the various steps of the process are described below.

Step a) uses a multilayer structure 60 formed at least partly of a first active layer in contact with a p-type or n-type first coating.

As is illustrated in FIG. 7, the multilayer structure 60 may advantageously be depicted by a support 8 on which are placed a succession of layers superposed on one another.

In one preferred embodiment, it may comprise:
a support 8,
a first electrode 11,
a first outer layer 14,
a first active layer 17,
a first coating 63.

In particular, the first outer layer and the first coating may consist of the n-type or p-type materials described above. The constituent layers of the multilayer structure 60 considered in step a) may be obtained by a wet route.

Thus, the first coating may be formed beforehand by depositing a solution on the outer surface of the first active layer under conditions suitable for its formation. This solution may comprise an n- or p-type material, in particular a p-type polymer and/or oxide, dissolved in a solvent, in particular as described above and may also comprise a surfactant and/or a viscosity agent as described above.

Preferably, this first coating has a thickness of between 20 nm and 100 nm.

The process carries out, in step b), a deposition on the first coating of a first solution comprising nanowires and optionally a p-type or n-type material, under conditions suitable for the formation, at the surface of said first coating, of a second coating incorporating an array of nanowires.

Step b) may lead to the formation of structurally different first and second coatings, depending on whether it is carried out according to a first mode or a second mode as described below.

In a first mode of implementation of step b), illustrated in FIG. 7, the first solution may then consist of a dispersion of nanowires in a solvent as described above. The concentration of nanowires, expressed as equivalent mass of silver constituting the nanowires per liter of first solution, is then preferably between 0.1 g/l and 10 g/l.

The first solution may be deposited on the first coating so as to form an array of nanowires by means of a deposition method as described above, and in particular by slot-die coating, or by photogravure, or by inkjet printing, or preferably by ultrasonic spray coating. A person skilled in the art knows how to adapt the deposition parameters in order to deposit a sufficient amount of nanowires so as to form a conductive array of nanowires after elimination of the solvent from the first solution.

Preferably, this first mode of implementation results, at the end of step b), in the formation of a second coating 64 formed by the array 22 of nanowires.

Preferably, the deposition parameters of the first solution are adapted so that, at the end of step b), the transmittance of the array of nanowires is greater than 70% and the surface resistivity of the array of nanowires is less than 50 Ω/sq, and/or the surface density of the array of nanowires, expressed as equivalent mass of silver constituting the nanowires per unit area, is between 0.005 g/m² and 0.1 g/m², more particularly between 0.01 g/m² and 0.05 g/m².

In a second mode of implementation of step b), illustrated in FIG. 8, the first solution deposited in step b) comprises a p-type or n-type material, as described above. In particular, the first solution in step b) may then be obtained by mixing first and second liquid preparations.

The p- or n-type of the material of the first solution deposited in step b) may be identical to or different from the p- or n-type of the material of the first coating.

The first liquid preparation may consist of a dispersion of nanowires in a solvent as described above in a concentration greater than or equal to 0.1 WI, preferably greater than or equal to 0.5 g/l, and less than or equal to 10 g/l, preferably less than or equal to 5 g/l.

The second liquid preparation may, for its part, comprise a weight content of p-type or n-type material of between 1% and 40%. In order to form the second liquid preparation, a p-type or n-type polymer is preferably dissolved in water. Alternatively, a p-type or n-type metal oxide may be dissolved in water and/or in an alcohol as described above. The second liquid preparation may in addition comprise a viscosity agent and/or a surfactant in order to modify the viscosity and/or the surface tension of the first solution.

The first solution, consisting of the first and second liquid preparations, is preferably deposited by spin coating, or by knife coating, or by ultrasonic spray coating, or by slot-die coating, or by inkjet printing.

In this second mode of implementation, the deposition parameters of the first solution are preferably adapted so that at the end of step b), the transmittance of the succession of the first coating 63, array of nanowires and second coating 64 is greater than 50% and the surface resistivity of the succession of the array of nanowires and of the second coating is less than 100 Ω/sq, and/or the surface density of the array of silver nanowires, expressed as equivalent mass of silver constituting the nanowires per unit area, is between 0.01 g/m² and 0.05 g/m².

In one variant, the process according to the invention may also comprise a step b′) carried out after step b) and before step c), consisting in depositing a solution comprising nanowires on the first coating formed in step b) under conditions suitable for the formation of a coating that is superposed on the first coating and on which the second coating is subsequently deposited. This solution then preferably comprises a material of the same n- or p-type as the first solution so that the first coating and the coating formed in step b′) define a homogeneous intermediate layer incorporating an array of nanowires having a variable density of nanowires depending on the thickness of the layer. Such a step b′) may in particular be carried out for the manufacture of a stack of use for a 3-terminal photovoltaic cell.

The process according to the invention also optionally carries out a step c) which consists in depositing, on the second coating formed in step b), a second solution comprising a p-type or n-type material, identical to or different from that of the first solution, under conditions suitable for the formation of a third coating (66).

Step c) is in particular carried out when, in step b), the first solution consists of a dispersion of nanowires in a solvent according to the first mode of implementation of the process as described above. Preferably, the second solution is then deposited directly on the array of nanowires formed in step b).

The second solution preferably comprises a p-type or n-type material in a solvent as described above. The second solution used in step c) may in particular be identical to that used in step a).

Preferably, the amount of second solution deposited in step c) is adapted so that after elimination of the solvent, the thickness of the third coating 66 is greater than the thickness of the array of nanowires formed at the end of step b). Preferably, the thickness of the third coating is between 50 nm and 400 nm.

Preferably, at the end of step c), the third coating incorporates at least partially, preferably completely, the second coating, in particular consisting of the array of nanowires, formed in step b).

In this way, the array of nanowires forms an electrically conductive structure within a matrix comprising a p-type or n-type material and formed at least in part by the third coating.

Preferably, the deposition parameters for the second solution are preferably adapted so that at the end of step c), the transmittance of the assembly formed by the first 63, second 64 and third 66 coatings is preferably greater than 50% and the surface resistivity of the third coating 66 is preferably less than 100 Ω/sq.

The coatings formed in steps a), b) and where appropriate c) form, depending on the way in which the process is carried out and depending on the choice of the n- or p-type of the materials forming the coatings, an intermediate layer alone or an intermediate layer and an additional layer of the stack.

In particular, the first coating may constitute the additional layer 41 on the one hand, and the second coating, and optionally the third coating, may constitute the intermediate layer 20 on the other hand.

As a variant, as illustrated for example in FIG. 7, the first 63, second 64 and optionally third 66 coatings constitute the intermediate layer 20.

In other words, the choice of the n- or p-type of the material constituting each of the coatings of steps a), b) and c) makes it possible to form, at the end of step b) or where appropriate of step c), a central electrode 70 or a multilayer charge carrier recombination element 45 of a photovoltaic cell comprising a stack according to the invention, as will be described below.

In particular, when, in step a), the first coating comprises an n-type, respectively p-type, material and when, in step b) and/or in step c), the second and/or the third coating comprise(s) an n-type, respectively p-type, material, the assemblage of the first, second and where appropriate third coatings constitutes the intermediate layer, incorporating an array of nanowires of n-type, respectively p-type, of the stack according to the invention.

Alternatively, when, in step a), the first coating comprises a p-type, respectively n-type, material and when, in step b) and/or in step c), the second and/or the third coating comprise(s) an n-type, respectively p-type, material, the first coating may constitute the additional layer of a stack according to the invention, of p-type, respectively n-type. The second coating and where appropriate the third coating may define the n-type, respectively p-type, intermediate layer of the stack according to the invention.

The process comprises a step d), that follows step c), consisting in depositing a second active layer, for example different from the first active layer, on the second coating formed in step b) or where appropriate on the third coating formed in step c). A person skilled in the art then knows how to determine the deposition conditions and the constituents of the solutions to be deposited so as to form a stack of use for a multi junction photovoltaic cell, in particular of tandem type, according to the invention.

Photovoltaic Cell

A multi junction organic photovoltaic cell, in particular of tandem type, according to the invention comprises a stack according to the invention or obtained by means of a process according to the invention.

In particular, as illustrated in FIGS. 1 to 4, it may comprise a succession of superposed layers that are contiguous with one another in the following order:
a support 8, preferably in the form of a plate, for example made of glass or plastic, preferably made of PEN and/or PET,
a first electrode 11, or lower electrode,
an assemblage formed completely or partly of a multilayer stack according to the invention as described above, and
a second electrode 29, or upper electrode.

The photovoltaic cell preferably comprises electrical connection means (not represented in FIG. 1), in particular contacts, that make it possible to connect the electrodes in order to supply an electric circuit with current.

The first electrode, in contact with the support, is for example formed from a layer made of a material selected from indium-doped tin oxide (ITO), aluminum-doped zinc oxide (AZO), gallium-doped zinc oxide (GZO), indium-doped zinc oxide (IZO) and mixtures thereof, or formed from an AZO/Ag/AZO multilayer assembly. It may also be constituted by an array of metal nanowires as described above, preferably consisting of silver nanowires.

The second electrode is preferably formed by a layer of silver, or by an array of nanowires, preferably silver nanowires.

In one embodiment, the photovoltaic cell may comprise a stack according to the first embodiment, that is to say comprising an intermediate layer inserted between and in contact with the first and second active layers.

It may then be such that the intermediate layer of the stack constitutes a central electrode 70, as illustrated in FIGS. 1 and 2. The first central electrode may be connected to the second electrode, by a conventional method known to a person skilled in the art. The first and second electrodes may be connected to the central electrode via an electric circuit. The tandem-type organic photovoltaic cell may thus be of “3-terminal” type.

As a variant, the photovoltaic cell according to the invention may comprise a stack according to the second embodiment, that is to say comprising an additional layer 41 inserted between the intermediate layer 20 on the one hand and the first active layer 17 or the second active layer 23 on the other hand. It may then be a “2-terminal” cell.

Preferably, the array 22 of nanowires, the intermediate layer 20 and the additional layer 41 of the stack form a multilayer recombination element 45 that favours the recombination of the charge carriers within the stack.

### EXAMPLES

The following nonlimiting examples are presented for the purpose of illustrating the invention.

### Example 1

The manufacture of the photovoltaic cell of example 1 is carried out by following the successive steps described below.

i) A polyethylene naphthalate (PEN) support is prepared in advance for the deposition of layers. Chromium/gold contacts are deposited on the support, then the support is degreased and treated with an oxygen plasma.

ii) A first electrode is formed on the support by depositing on one face of the support, by ultrasonic spray coating, a solution of silver nanowires diluted in methanol to a content of 0.5 grams per liter of methanol. This deposition is performed by carrying out several successive sweeps over the face of the support until an array of silver nanowires is formed on the surface of the support that has an electrical surface resistivity of greater than 10 Ω/sq and less than 50 Ω/sq. The array of nanowires is then compressed using a press at a temperature of 80° C., for 30 minutes. After this treatment, the surface resistivity and the transmittance are measured and are respectively less than 25 Ω/sq and approximately equal to 90%.

iii) A first n-type ZnO coating is then deposited on the first electrode. For this, a solution is prepared comprising 6% of ZnO, as a weight percentage relative to the weight of the solution, the rest consisting of ethanol. It is spin coated for 30 seconds, the speed of rotation of the spin coater being set at 1000 rpm. The contacts are then washed with a cotton swab impregnated with isopropanol (IPA). The multilayer structure obtained by these first depositions of layers is then annealed for 5 minutes at a temperature of 140° C.

iv) A mixture consisting, in parts by volume, of 93% orthodichlorobenzene (oCDB) and of 7% methylnaphthalene is then prepared as solvent. Added to this solvent are 38 grams per liter of poly(3-hexylthiophene) (P3HT) and methyl [6,6]-phenyl-C61-butanoate (PCBM) solvent, the ratio of the mass of P3HT to the mass of PCBM being 1/0.88, so as to form a solution for the deposition of a first active layer. This solution is then spin coated on the multilayer structure, with the spin coater rotating at a speed of rotation of 1500 rpm for 40 seconds, so as to form a first active layer on the first ZnO coating previously formed. The contacts are then washed with oCDB, then the multilayer structure so far comprising the first active layer is annealed for 10 minutes at a temperature of 120° C.

v) A first coating of a PEDOT and PSS mixture (also known as PEDOT:PSS), is then formed on the multilayer structure formed in the preceding step, by spin coating a PEDOT:PSS solution of Heraeus HTL Solar trade name, firstly at a speed of rotation of 1500 rpm for 25 seconds, then at a speed of 3000 rpm for 25 seconds. The contacts are then washed with isopropanol or deionized water. The substrate is then annealed at a temperature of 120° C. for 10 minutes in a glove box.

vi) An array of silver nanowires is formed on the PEDOT:PSS coating in a manner identical to that described in step i).

vii) A second PEDOT:PSS coating is formed on the array of nanowires formed in step vi) according to the method described in step v).

viii) A second active layer is formed on the second layer of PEDOT:PSS by following a method identical in every respect to that described in step iv).

Thus, the first PEDOT:PSS coating, the array of nanowires formed in step vi) and the second PEDOT:PSS coating together define a central electrode in the form of an intermediate layer in contact with the first and second active layers.

ix) A second n-type ZnO coating is then formed on the second active layer under conditions identical to those described in step iii), the speed of rotation of the spin coater being set at 2000 rpm.

x) Finally, a second silver electrode having a thickness of 100 nm is formed on the multilayer structure obtained in step ix) by vacuum evaporation.

In this way, an NIPIN assemblage is obtained as illustrated for example in FIG. 7.

A “three-terminal” tandem-type organic photovoltaic cell comprising the assemblage obtained with the aid of steps i) to x) described above has a mean efficiency of 3%, 0.5 points greater than the efficiency of a conventional tandem organic photovoltaic cell having a central electrode consisting of a silver film deposited by vacuum evaporation.

### Example 2

Example 2 differs in particular from example 1 in that the support is made of glass and the lower electrode is made of indium tin oxide (ITO).

The assemblage is obtained by following steps i) to x) of example 1. It has a mean efficiency of 3%, 0.5 points greater than the efficiency of a conventional tandem cell having a central electrode consisting of a silver film deposited by vacuum evaporation.

### Example 3

The preparation of example 3 only differs from example 1 in that the steps vii) and ix) are inverted so as to respectively form steps ix′) and vii′), the speed of rotation in step vii′) nevertheless being set at 1000 rpm.

Thus, the first PEDOT:PSS coating and the array of nanowires formed in step vi) form an intermediate layer; the second ZnO coating formed in step vii′) constitutes an additional layer. These intermediate and additional layers together form a multilayer element for recombination of charge carriers.

In this way, an NIP/NIP assemblage is obtained. A “two-terminal” tandem-type organic photovoltaic cell incorporating the stack from example 3, as represented schematically in FIG. 5, has a mean efficiency of 3%, 0.5 points greater than the efficiency of a conventional tandem-type organic photovoltaic cell having a charge-carrier recombination layer consisting of a silver film deposited by vacuum evaporation.

The invention is very obviously not limited to the embodiments described and represented.

1. A multilayer stack useful for forming an organic photovoltaic cell of multi-junction type, said stack comprising first and second active layers, and a p-type or n-type intermediate layer, inserted between said first and second active layers and in contact with at least one of the first and second active layers, said intermediate layer incorporating an array of electrically conductive nanowires, the multilayer stack comprising an additional layer, inserted between the first active layer and the second active layer and directly in contact with the first active layer or with the second active layer, the additional layer being of p- or n-type, different from that forming the intermediate layer.

2. The stack as claimed in claim 1, the array of nanowires extending parallel to the intermediate layer.

3. The stack as claimed in claim 1, the array of nanowires having no contact with said first and second active layers.

4. The stack as claimed in claim 1, a thickness of the intermediate layer being greater than or equal to 100 nm and less than or equal to 500 nm.

5. The stack as claimed in claim 1, the array of nanowires being at least partially in contact with the additional layer.

6. The stack as claimed in claim 1, the array of nanowires extending to the interface between the intermediate layer and the additional layer.

7. The stack as claimed in claim 1, the array of nanowires being non-percolating.

8. The stack as claimed in claim 1, wherein an assembly formed by the intermediate layer and the additional layer has a thickness greater than or equal to 100 nm and less than or equal to 500 nm.

9. The stack as claimed in claim 1, the transmittance of an assembly formed by the intermediate layer and the additional layer being greater than 50%.

10. The stack as claimed in claim 1, the surface resistivity of an assembly formed by the intermediate layer and the additional layer being less than 200 Ω/sq.

11. The stack as claimed in claim 1, the nanowires being metallic.

12. The stack as claimed in claim 1, the nanowires having a mean diameter greater than or equal to 10 nm and less than or equal to 1000 nm, and having a mean length greater than or equal to 1 μm and less than or equal to 500 μm.

13. The stack as claimed in claim 1, a material of the intermediate layer and/or of the additional layer being selected from the group formed by:
p-type polymers and p-type oxides, in particular the mixture of poly(3,4-ethylenedioxythiophene) (PEDOT) and of sodium poly(styrene sulfonate) (PSS), Nafion, WO₃, MoO₃, V₂O₅ and NiO and mixtures thereof,
or
n-type polymers and n-type oxides, in particular polyethylenimine ethoxylated (PEIE), poly[(9,9-bis(3′-(N,N-dimethylamino)propyl)-2,7-fluorene)-alt-2,7-(9,9-dioctylfluorene) (PFN), ZnO, titanium oxides TiOₓ with x between 1 and 2, aluminum-doped zinc oxide (AZO), indium-doped zinc oxide (IZO), gallium-doped zinc oxide (GZO), and mixtures thereof.

14. A process for manufacturing a stack, comprising:
a) placing a first active layer in contact with a first coating of p-type or n-type,
b) depositing on said first coating a first solution comprising nanowires and optionally a p-type or n-type material, under conditions suitable for the formation, at the surface of said first coating, of a second coating incorporating an array of nanowires,
c) optionally, depositing on the second coating formed in step b) a second solution comprising a p-type or n-type material, different from that of the first solution, under conditions suitable for the formation of a third coating,
the first coating forming the additional layer, and the second coating, and optionally the third coating, forming the intermediate layer, of a stack as claimed in claim 1.

15. The process as claimed in claim 14, comprising a step d), that follows step c), comprising forming a second active layer on the second coating formed in step b) or on the third coating formed in step c).

16. An organic photovoltaic cell of multi-junction type, and in particular of tandem type, comprising a multilayer stack useful for forming an organic photovoltaic cell of multi-junction type, said stack comprising first and second active layers, and a p-type or n-type intermediate layer, inserted between said first and second active layers and in contact with at least one of the first and second active layers, said intermediate layer incorporating an array of electrically conductive nanowires, the multilayer stack comprising an additional layer, inserted between the first active layer and the second active layer and directly in contact with the first active layer or with the second active layer, the additional layer being of p- or n-type, different from that forming the intermediate layer or obtained by means of a process in accordance with claim 14.

17. The photovoltaic cell as claimed in claim 16, in which the array of nanowires, the intermediate layer and the additional layer of the stack form a multilayer element for recombination of charge carriers.
